(19) United States
(12) Patent Application Publication
(10) Pub. No.: US 2008/0204016 A1
(43) Pub. Date: Aug. 28, 2008

(54) Magnetic Resonance Apparatus and Method

(76) Inventors: Ian Leitch McDougall, Oxon (GB); Peter Hanley, Gloucestershire (GB)

Correspondence Address: BLANK ROME LLP, 600 NEW HAMPSHIRE AVENUE, N.W., WASHINGTON, DC, 20037, US

(21) Appl. No.: 11/913,019

(22) PCT Filed: Apr. 10, 2006
(86) PCT No.: PCT/GB2006/001309

§ 371 Date: May 7, 2008

(30) Foreign Application Priority Data
Apr. 29, 2005 (GB) 0508890.1

(51) Int. Cl. G01R 33/44

(52) U.S. Cl. 324/309; 324/320

(57) ABSTRACT

Magnetic resonance apparatus is provided comprising a magnet having a first pair of coils arranged in a plane. The coils are operable in a counter-running manner when in use so as to generate a sensitive volume of magnetic field spaced apart from said plane. The magnetic field in the sensitive volume is arranged to have sufficient uniformity to enable magnetic resonance signals to be obtained from a target when located within the sensitive volume. The magnetic field direction Z is oriented to lie substantially parallel to the planes. The coils are arranged such that the sensitive volume is elongate in a direction X substantially parallel to the planes. A drive system is provided to cause relative movement between the magnet and the target so as to allow the sensitive volume to be moved with respect to the target.

The present invention relates to a magnetic resonance apparatus and method.

Proposals for “Open Access” MRI systems generally suffer from a number of disadvantages as a direct consequence of the requirement to generate a substantial volume of intense, uniform magnetic field external to the magnet device. Typically, these disadvantages include:
Because an open-access (external field, single-sided) magnet system is inherently asymmetrical, a three-dimensional volume of field homogeneity requires the use of counter-running coils, or other negative magnet elements;
Counter running coils increase complexity, bulk and cost of the magnet system, and reduce its efficiency;
These factors make the achievement of a strong magnetic field, uniform over a large volume, difficult or impossible;
A further consequence of the “external field” or “single-sided” concept is the existence of a large stray field that reduces the acceptability of such systems in environments such as hospitals.

Some of these issues are addressed in our earlier British patent application 0414431.7. The disclosure of that application is incorporated herein by reference, in its entirety, including the examples. While reducing stray field substantially in comparison with external field designs, the apparatus disclosed in that patent application still requires the use of counter-running magnet elements to achieve a substantial three-dimensional homogeneity volume with a consequent reduction in efficiency and achievable field strength.

In accordance with a first aspect of the present invention, we provide a magnetic resonance apparatus comprising:—

a magnet having a first pair of coils arranged in a plane, the coils being operable in a counter-running manner when in use so as to generate a sensitive volume of magnetic field spaced apart from said plane, the magnetic field in the sensitive volume having sufficient uniformity to enable magnetic resonance signals to be obtained from a target when located within the sensitive volume, the magnetic field direction z lying substantially parallel to said planes, and wherein the coils are arranged such that the sensitive volume is elongate in a direction X substantially parallel to said planes; and,

a drive system adapted in use to cause relative movement between the magnet and the target so as to allow the sensitive volume to be moved with respect to the target.

We have therefore adopted a new approach in obtaining signals from a sensitive volume. Whereas in the past the focus has been on achieving ever larger volumes of high homogeneity, we have realised that a great deal of benefit can be obtained by using magnets to produce a sensitive volume, together with a drive system to cause relative movement between the magnet and the target such that the sensitive volume is moved with respect to the target. The present invention therefore provides a single-sided system with a low stray field. One particular problem with single-sided systems is that it is difficult to obtain a large sensitive volume due to the inherent asymmetry in the system. The present invention avoids the need to provide ever more powerful magnets by accepting that the sensitive volume may be small. The problem is then addressed by the volume being moveable with respect to the target.

We have realised that the dimensionality of the homogeneous volume can be conveniently reduced to that of a line. In our earlier patent application GB0414431.7 the arrangement disclosed is used to produce an extensive plane of substantial homogeneity. In the present invention we have adopted a different approach by reducing the sensitive volume to a line, that is an elongate volume of small cross-sectional dimensions. This line is then scanned through a plane in the target, and if required, this line or plane can be scanned through the target to provide information in a third direction.

In such a single-sided system the sensitive volume is arranged to be to one side and separate from the plane. Typically, each of the coils has an axis that is substantially perpendicular to the turns of the coil and is also substantially perpendicular to its respective plane. Ordinarily, each of the coils of the first pair is elongate in the X direction. Such coils may take a “racetrack” form. Parts of each coil within the first pair may be rectilinear in the X direction. Indeed preferably each of the first pair of coils has two parallel rectilinear parts, these being joined by a single curve at each end. The coils are typically of the same length in the X direction. In an alternative arrangement, each of the coils of the first pair may comprise a set of sub-coils (such as circular coils) arranged side-by-side in the X direction so as to act together as an elongate coil. Each of the elongate coils of the system may be so formed. This may be advantageous in some cases, for example where the coils are formed from high temperature superconducting materials,

In order to control the extent of the sensitive volume in the X direction, two pairs of correction coils may be provided. One pair of these may be located at each end of the elongate coils for this purpose. The correction coils are typically arranged in a plane parallel with the plane of the first pair. They may be coplanar with the first pair, if suitably sized. The correction coils may have a circular geometry although other geometries could be chosen depending on how the sensitive volume is designed to be controlled in geometry.

The invention is not limited to a particular type of material for use in the electromagnetic coils. The invention may therefore be implemented using resistive coils or superconducting coils. Superconducting coils provide an advantage in terms of the strength of the magnetic field achieved (due to the high currents available) although of course there is detrimental low temperature operation requirement associated with these. Preferably therefore the coil materials are superconducting and most preferably they are formed from high temperature superconducting materials which are now available commercially.

The drive system provides the relative movement between the magnet and the target so as to achieve the desired movement of the sensitive volume. Preferably the drive system is adapted to move the sensitive volume in a working plane with respect to the target. The drive system may therefore be adapted to rotate the sensitive volume about a point lying on a line defined by an elongate axis of the sensitive volume. This point might lie substantially in the centre of the sensitive volume, in which case the sensitive volume can be caused to rotate in a similar manner to a linear radar antenna. The point of rotation may also be located at substantially one end of the sensitive volume such that the line defining the sensitive volume traces out a circular area, semi-circular area or any part thereof. Each of these approaches allows the magnetic resonance information to be obtained from a substantially planar region. Linear translations are also contemplated in addition to rotational or orbital motions.

Preferably the system is further adapted to move the sensitive volume in a direction having at least a component normal to the working plane with respect to the target. Such movement is preferably in a substantially normal direction to the working plane. The working plane can therefore be thought of as an X-Z plane, with the direction as the third dimension being in the Y direction.

The drive system may be adapted to move the target with the magnet remaining stationary. Alternatively, the magnet might be moved, with the target remaining stationary. As a further alternative, each of the magnet and target may be moved relative to an external reference, whilst also ensuring mutual relative movement.

The apparatus typically comprises a set of gradient coils for producing a gradient in the magnetic field Z along the X direction within the sensitive volume. This is important in imaging applications to ensure that different parts along the sensitive volume experience different magnetic field strengths in the Z direction. The gradient coils may take the form of pairs of coils at or adjacent each respective end of the first pair, in a similar manner to the correction coils although, in this case, those at one end are of dissimilar magnetic field strength to those at the other.

In another approach the gradient coils may be generally similar in form to the first pair, such as racetrack coils or a set of coils that act together as an elongate coil. In order to ensure that a gradient exists along the length of the sensitive volume in this approach, these elongate gradient coils may be preferably of a different length (typically longer) than the first pair, preferably coplanar with the first pair and at least have a centroid that is offset in the direction of elongation with respect to the centroid of the first pair. The gradient coils are therefore asymmetrically located along the direction of elongation, with respect to the first pair. In principle the gradient coils in this case could be formed as part of the main magnet coils (in series with the first pair). However, since the magnetic field required to produce the desired gradient is much smaller than that required to produce the main field, typically the gradient coils are separate coils that can be controlled independently of the main magnet coils (first pair).

Because a drive system is used to sweep the sensitive volume through the target, in many cases it is not necessary to switch the currents within the gradient coils. This is extremely desirable since it removes one of the most common causes of anxiety for patients in MRI scanners, namely becoming distressed by the noise caused by rapid switching of currents within the gradient coils. The much sought-after “quiet” or “silent-running” MRI system is therefore a possibility as part of the present invention.

In some cases however it may be desirable to change the magnetic gradient along the sensitive volume. One example of this is where only one part of the sensitive volume is of interest and the gradient is switched between an initially low level for performing a general scan, to a higher level for localised high resolution imaging.

The system typically also comprises one or more transmit and/or receive coils for obtaining the magnetic resonance signals from the target when the target intersects the sensitive volume.

The first pair of coils may be arranged such that each coil has opposing ends that are angled out of the corresponding plane so as to increase the homogeneity of the region within the direction X in comparison with similar coils laying wholly within the plane. A suitable technique for this is disclosed in the British patent application 0414431.7, mentioned earlier.

In accordance with a second aspect of the present invention, we provide a method of using the magnetic resonance apparatus of the first aspect, the method comprising
a) positioning the sensitive volume at a first position with respect to the target;
b) operating the apparatus to obtain magnetic resonance signals from the target within the sensitive volume;
c) operating the drive system to cause the sensitive volume to move to a different position with respect to the target; and,
d) repeating steps b and c so as to obtain magnetic resonance signals from a number of different positions.

The invention therefore finds primary application in the field of magnetic resonance imaging, for example where the target is a life form. The apparatus therefore has many advantages in the field of medicine and veterinary science. Furthermore, the apparatus may also be used in NMR type experiments in for example determining the internal structure of a workpiece or member. This might involve for example analysing a composite structure for internal flaws.

Some examples of a magnetic resonance apparatus and method according to the invention will now be described, with reference to the accompanying drawings, in which:

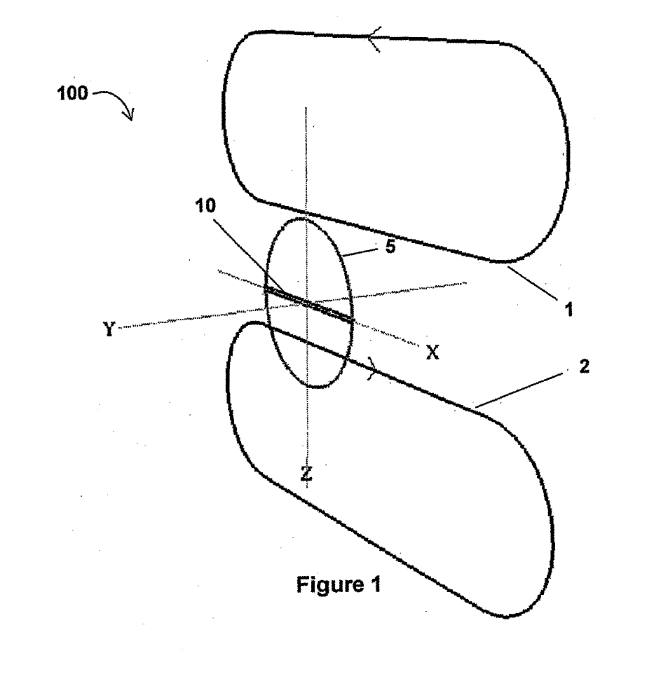

FIG. 1 shows a schematic view of a first example system;

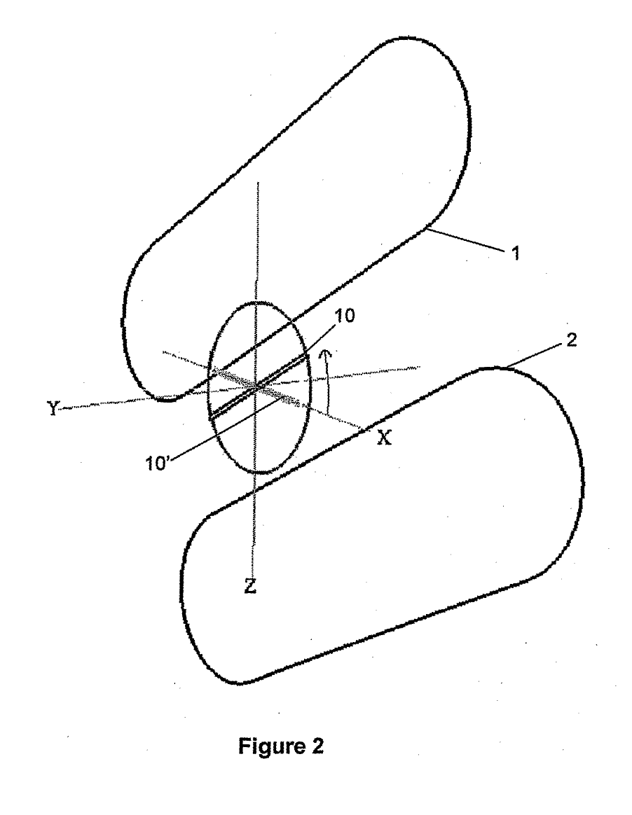

FIG. 2 shows rotation of the sensitive volume in the X-Z plane;

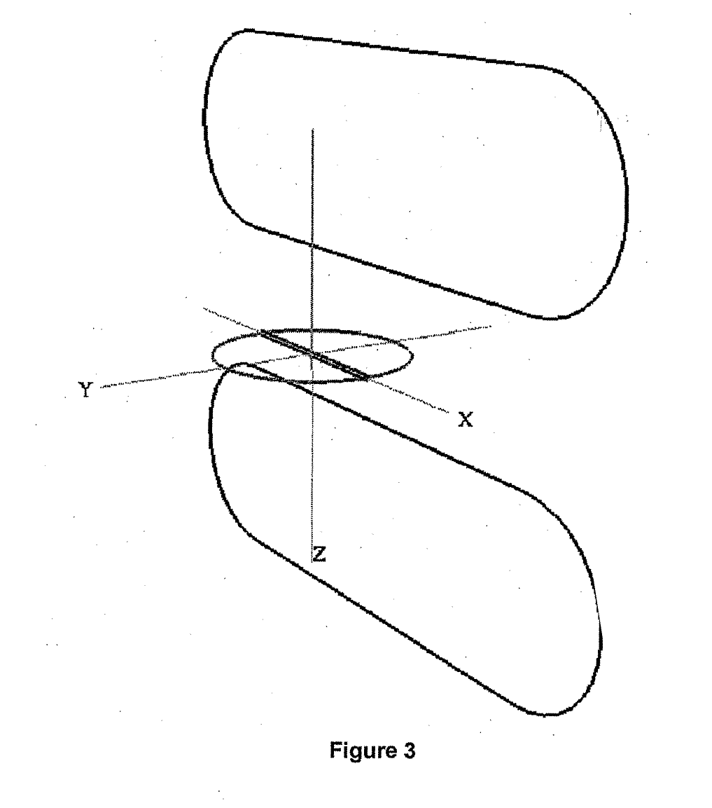

FIG. 3 shows rotation of the sensitive volume in the X-Y plane;

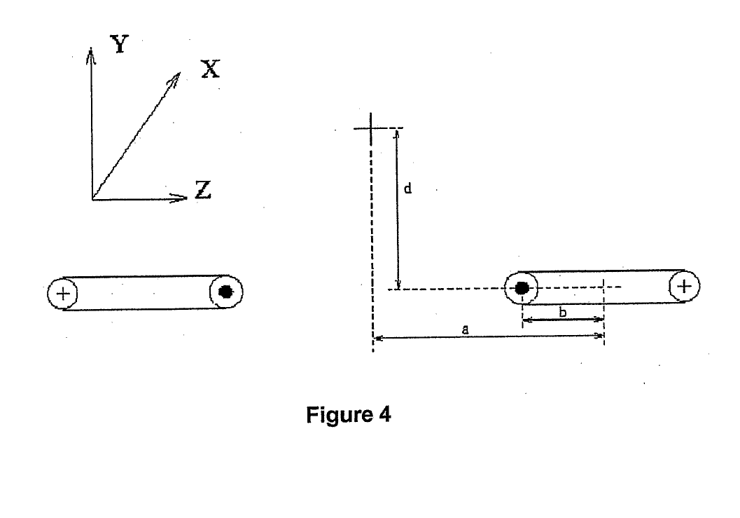

FIG. 4 shows the notation system used in describing the coils;

FIG. 5 is an example spreadsheet showing the relationship between proposed coil dimensions and calculated gradients;

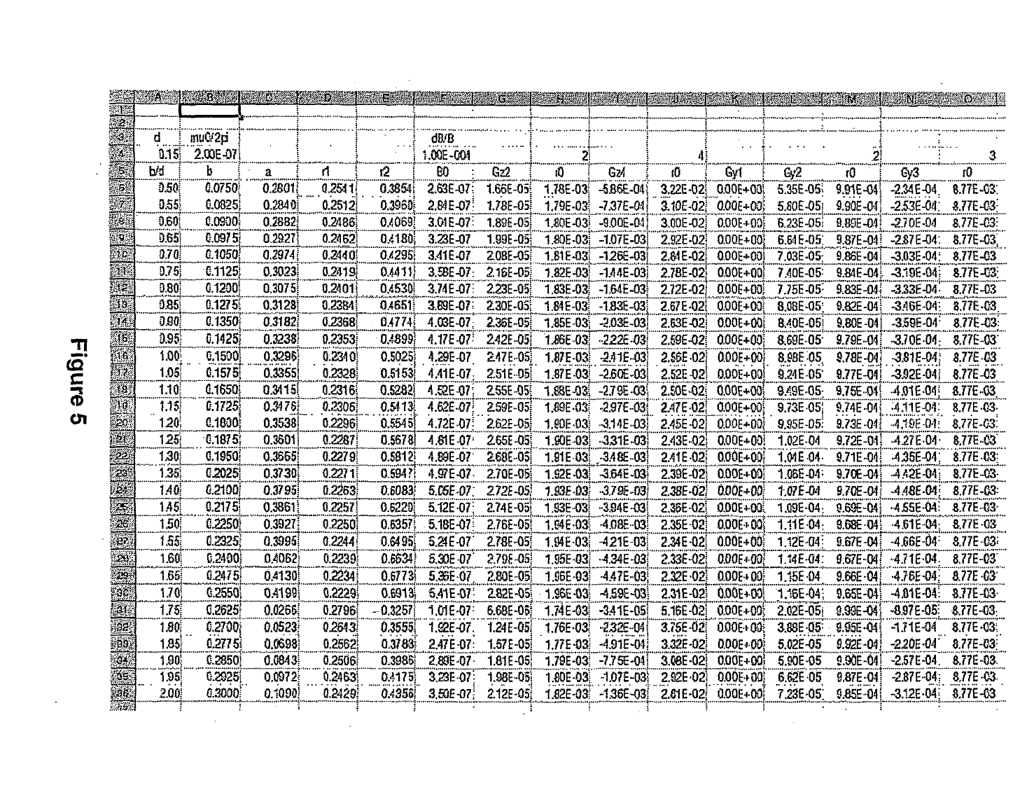

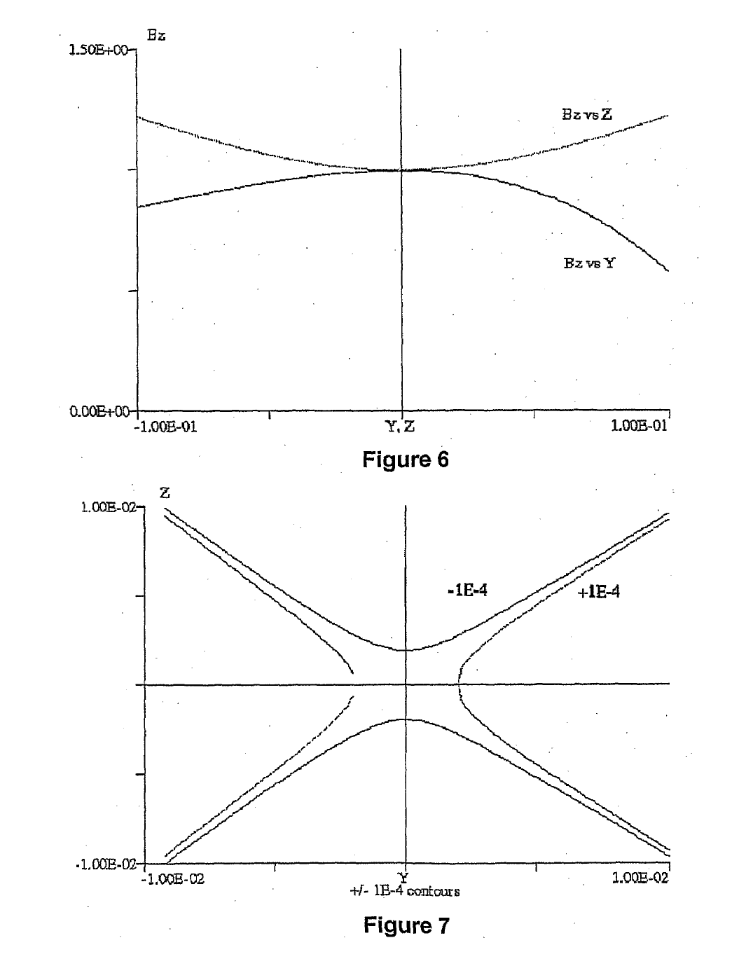

FIG. 6 shows the strength of the Z component of the magnetic field as a function of position from the origin for one particular coil arrangement;

FIG. 7 shows field contours for the system of FIG. 6, having a homogeneity of 100 parts per million;

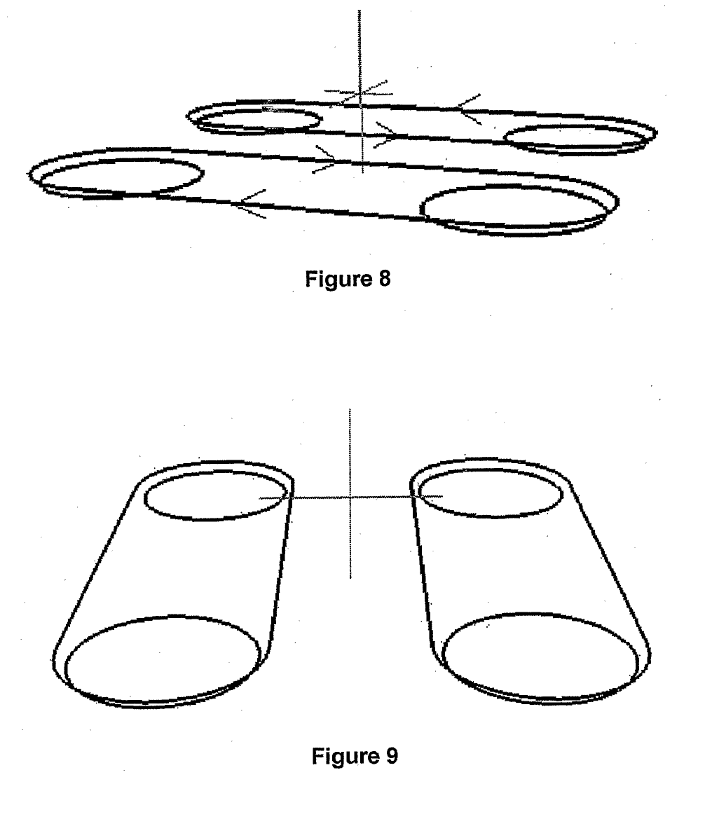

FIG. 8 shows an example using correction coils;

FIG. 9 shows a second view of the example having correction coils;

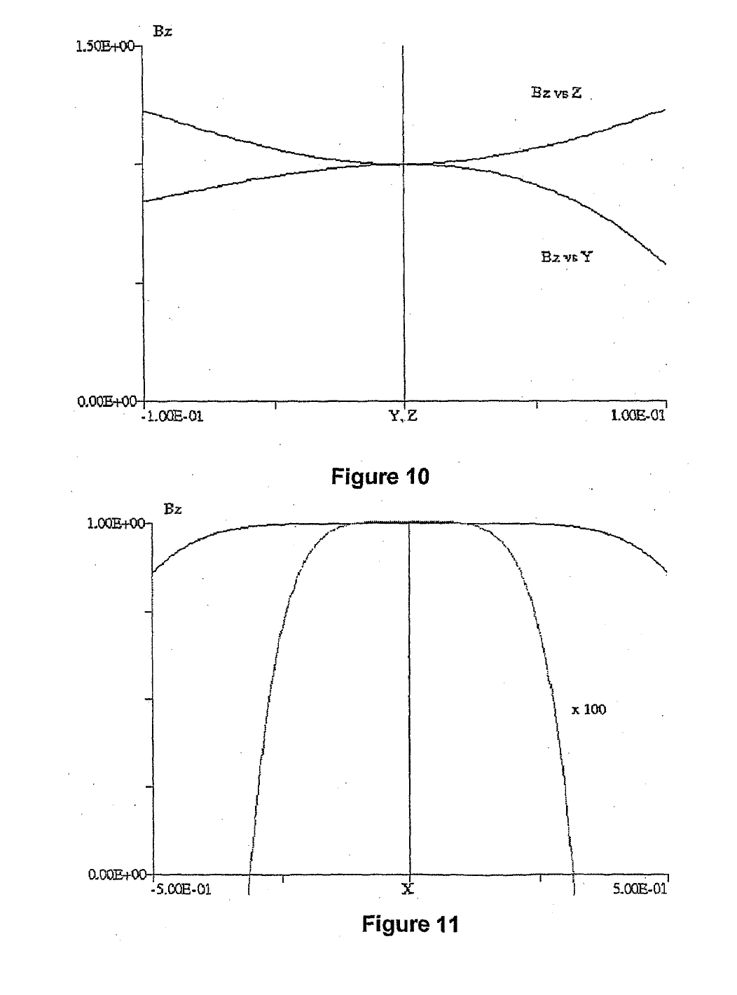

FIG. 10 shows the magnetic field in the Y and Z directions of the example having correction coils;

FIG. 11 shows the magnetic field in the X direction of the example having correction coils;

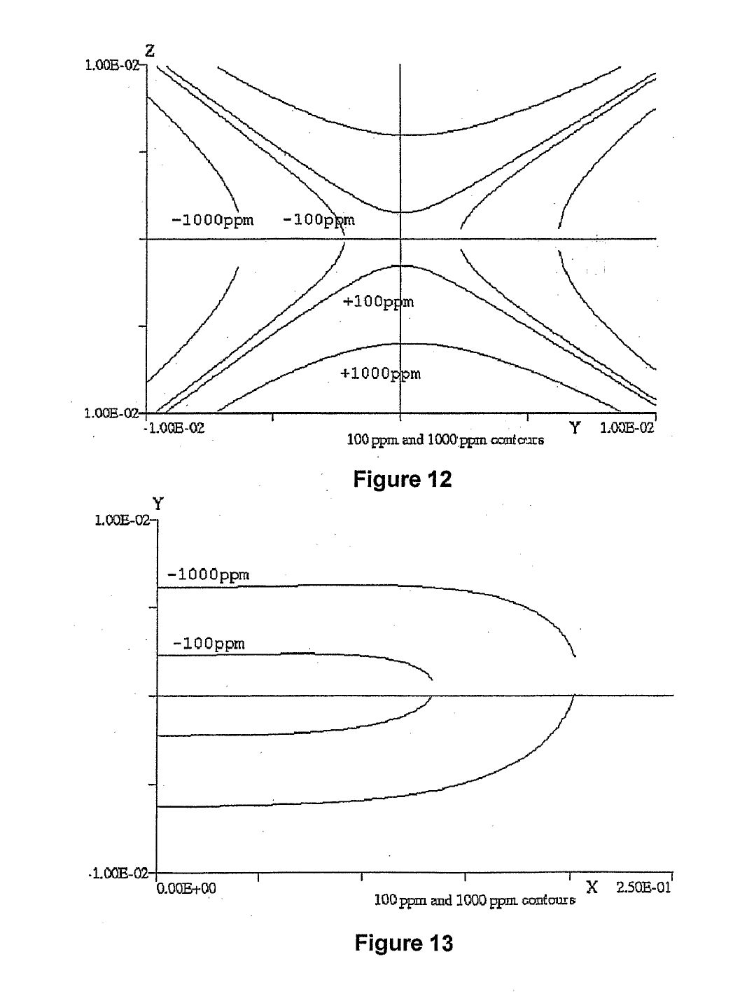

FIG. 12 shows the field contours of 100 and 1000 ppm in the Y-Z plane;

FIG. 13 shows the field contours of 100 and 1000 ppm in the X-Y plane;

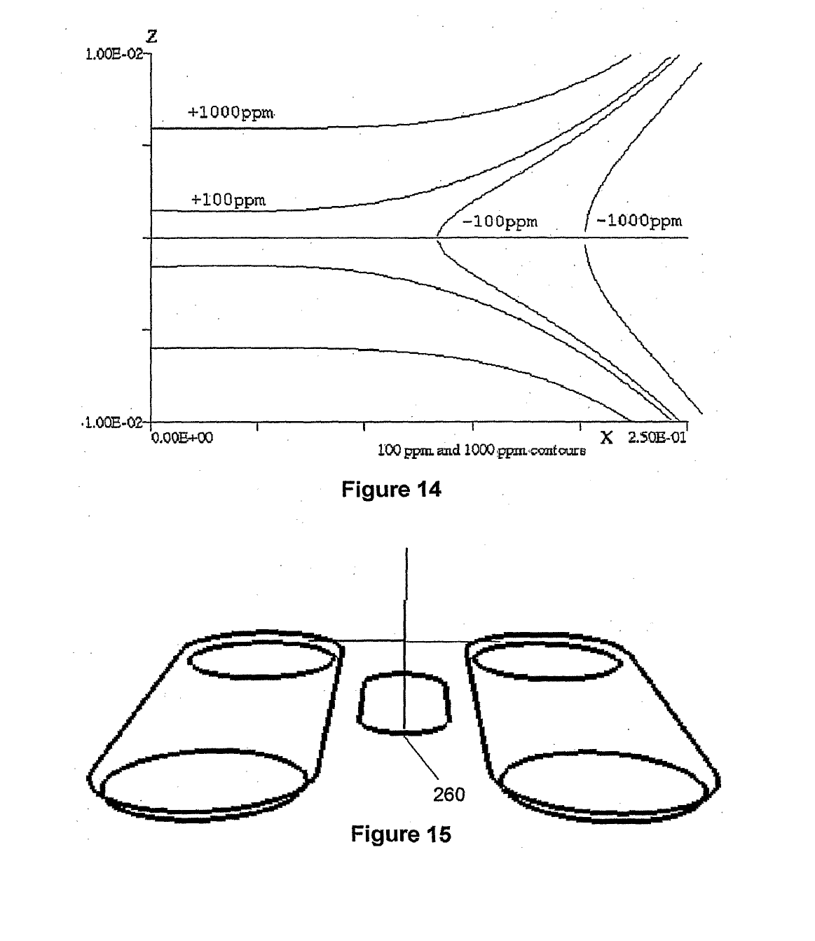

FIG. 14 shows the field contours of 100 and 1000 ppm in the X-Z plane;

FIG. 15 shows the position of an RF coil for use with the example systems;

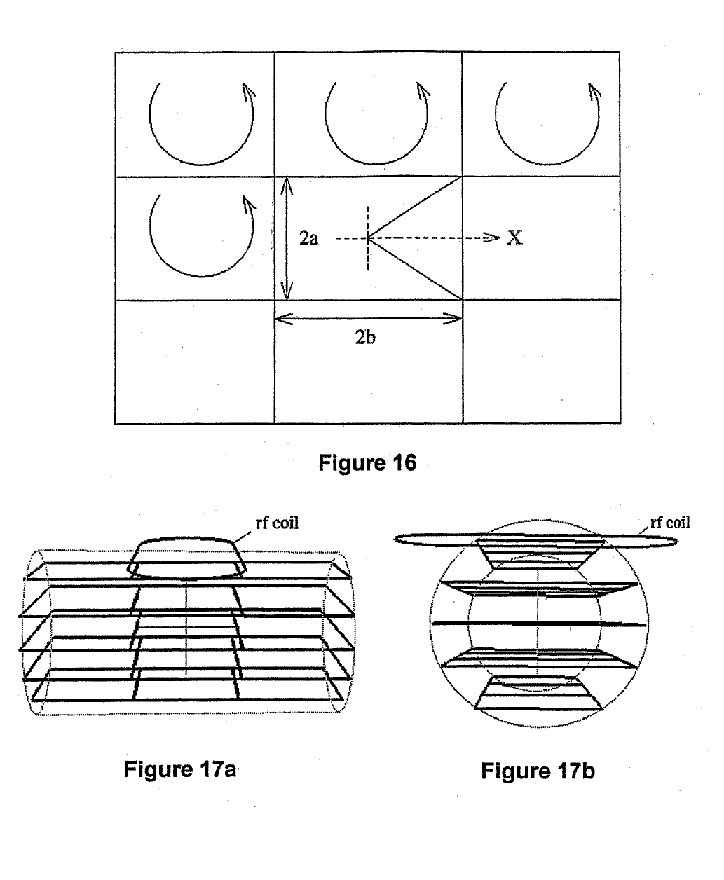

FIG. 16 illustrates a method of calculating the effective noise resistance of the subject;

FIG. 17a shows a first view of a subdivided cylindrical region for the effective noise resistance calculation;

FIG. 17b shows an end view of the subdivided cylinder region of FIG. 17a;

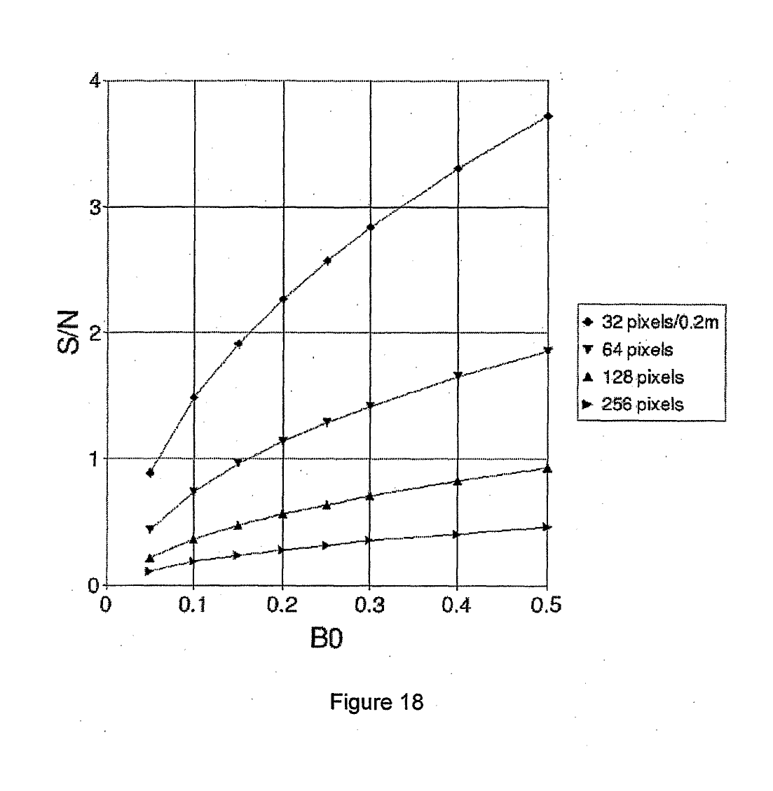

FIG. 18 shows the estimated signal to noise ratio as a function of resolution along the X-direction;

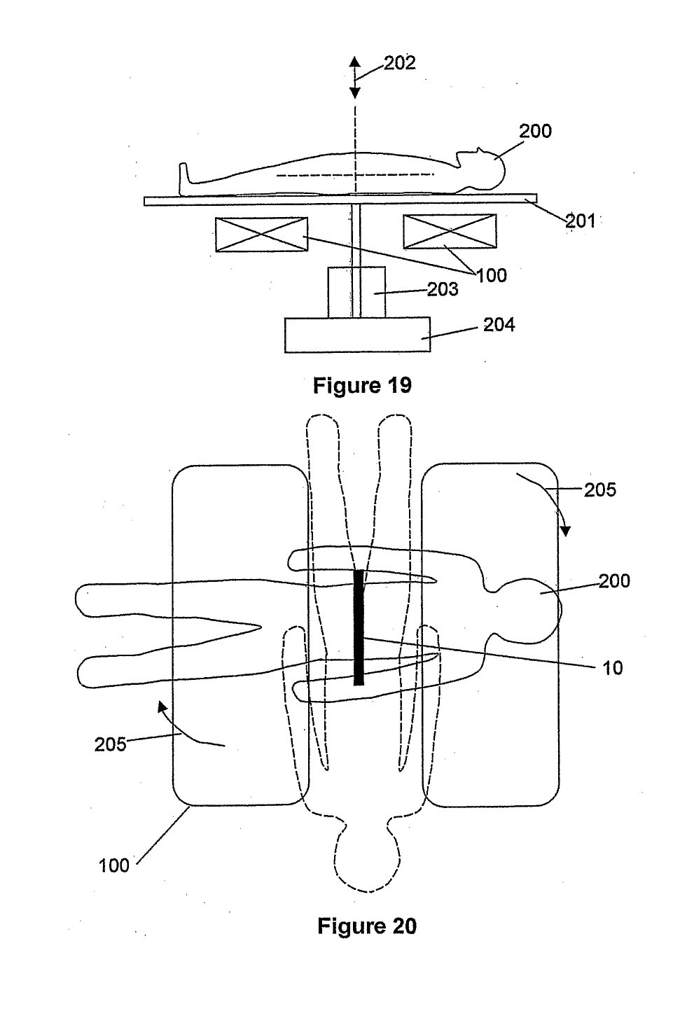

FIG. 19 is a side view of an example system illustrating how a patient can be moved with respect to the magnet system;

FIG. 20 is a top view of FIG. 19;

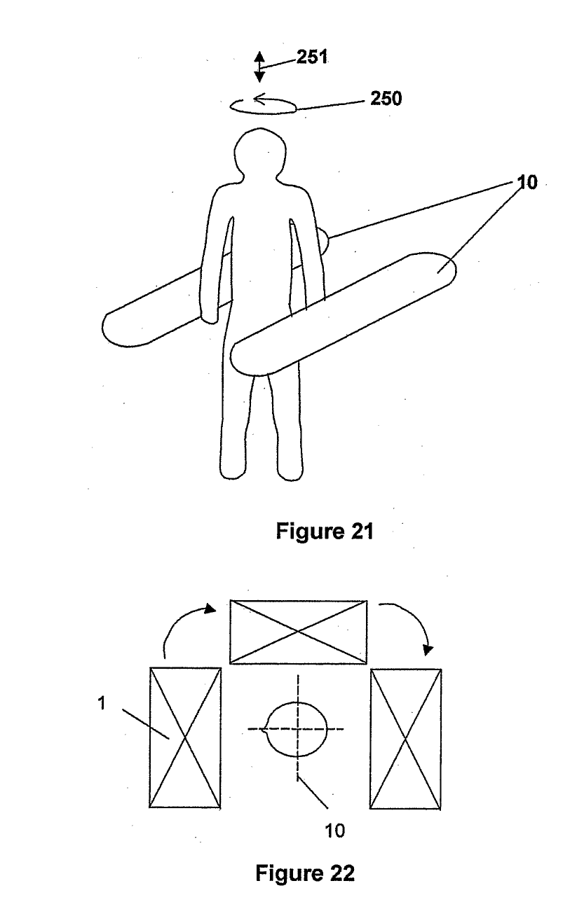

FIG. 21 shows a patient standing example; and

FIG. 22 shows a further example for imaging a head by moving the magnet.

Consider magnet system 100 illustrated in FIG. 1. The magnet consists of a pair of “racetrack” coils 1,2 lying in a plane parallel to the X-Z plane and offset from it by a distance −d in the Y-direction. The centroids of the coils define the plane. As will be described later, these coils produce a magnetic field in the Z-direction near the origin, and this can be arranged to be uniform over a substantial distance in the X-direction and over a small distance in the Y and Z directions. This volume of uniformity defines a sensitive volume 10 that is long, narrow and approximately cylindrical. Although it can be advantageous to have additional correction coils which increase the length of the volume of uniformity relative to the length in the X-direction of the magnet system, these coils are not counter-running and so the efficiency of the magnet is high, and the field strength can be greater than for other “external field” or “single-sided” systems. It also has the particular advantage that the spatial extent of the stray field is moderate.

If the magnet system is rotated about the Y-axis, the cylindrical sensitive volume 10 sweeps out a circular slice 5 in the X-Z plane. By stepping through a rotation of 180° a series of line scans can be used to, in the case of MRI, build up an image of a cross-section of the subject (not shown) in this plane. This rotation is shown in FIG. 2 where the sensitive volume 10 is rotated about the Y-axis by about 40° and adopts a position illustrated at 10′.

Alternatively, the magnet system could be rotated about the Z-axis as shown in FIG. 3 to produce a slice in the X-Y plane.

Alternatively, the magnet system could be translated in the Y-direction or the Z-direction to produce a rectangular slice in the X-Z or X-Y planes respectively.

As will be appreciated, a practical system would include appropriate radio-frequency coils and a coil producing a magnetic field gradient in the X-direction to produce the line scan. It would also include a control system and, for superconducting magnet coils, a cryogenic cooling system.

This procedure is to be distinguished from that described by Lauterbur, PC, Nature, 190, 242, (1973) where the volume of uniformity extends over all the region of interest, and the direction of an applied field gradient is rotated, with the image being produced by the projection reconstruction technique.

It is also to be distinguished from the techniques of Hinshaw and Bottomley, Hinshaw, W S and Bottomley, P A, Nature 270, 722 (1977), and of Damadian R, U.S. Pat. No. 3,789,832 (1972) which involve the scanning of a single point over the subject volume. Each of these existing methods presupposes the existence of a magnet of restricted access producing an intense, substantially uniform background field.

Magnet

Because this is a “line-at-a-time” method of obtaining magnetic resonance information such as imaging, and is therefore slower than a plane-at-a-time method, a strong field is required to obtain good sensitivity and hence minimise the imaging time. Such requirements are best met by a system without counter-running coils. We therefore attempt to obtain the homogeneity in the Z-Y plane using the dimensions of a single pair of coils only. However, a system of compensation will be needed to make the field sufficiently uniform in the X-direction. It is also necessary that the magnetic field be single-valued over the field of view to allow the line to be selected unambiguously.

FIG. 4 shows the notation and arrangement from which the following expressions for the field gradients can be derived:

$$\begin{matrix}{B}_{0} = {G}_{y 0} = {G}_{z 0} = \frac{{μ}_{0} I}{2 π} d \{ \frac{1}{{r}_{1}^{2}} - \frac{1}{{r}_{2}^{2}} \} \\ {G}_{y 1} = - \frac{{μ}_{0} I}{2 π} \{ \frac{1}{{r}_{1}^{2}} - \frac{1}{{r}_{2}^{2}} - 2 {d}^{2} ( \frac{1}{{r}_{1}^{4}} - \frac{1}{{r}_{2}^{4}} ) \} \\ {G}_{y 2} = - \frac{{μ}_{0} I}{2 π} d \{ \frac{6}{{r}_{1}^{4}} - \frac{6}{{r}_{2}^{4}} - 8 {d}^{2} ( \frac{1}{{r}_{1}^{6}} - \frac{1}{{r}_{2}^{6}} ) \} \\ {G}_{y 3} = \frac{{μ}_{0} I}{2 π} \{ \frac{6}{{r}_{1}^{4}} - \frac{6}{{r}_{2}^{4}} - 48 {d}^{2} ( \frac{1}{{r}_{1}^{6}} - \frac{1}{{r}_{2}^{6}} ) + 48 {d}^{4} ( \frac{1}{{r}_{1}^{8}} - \frac{1}{{r}_{2}^{8}} ) \} \\ {G}_{z 2} = - \frac{{μ}_{0} I}{2 π} 2 d \{ \frac{1}{{r}_{1}^{4}} - \frac{1}{{r}_{2}^{4}} - 4 ( \frac{{( b - a )}^{2}}{{r}_{1}^{6}} - \frac{{( b + a )}^{2}}{{r}_{2}^{6}} ) \} \\ {G}_{z 4} = \frac{{μ}_{0} I}{2 π } 24 d \{ \frac{1}{{r}_{1}^{6}} - \frac{1}{{r}_{2}^{6}} + 8 ( \frac{{( b - a )}^{2}}{{r}_{1}^{8}} - \frac{{( b + a )}^{2}}{{r}_{2}^{8}} ) \} \\ where {r}_{1}^{2} = {d}^{2} + {( b - a )}^{2} and {r}_{2}^{2} = {d}^{2} + {( b + a )}^{2}\end{matrix}$$

A method of controlling the homogeneity is to correct the field profile in the Y-direction, thus:

It can be previously shown that G_{y1}=0 for

$$\begin{matrix}a = \begin{matrix}\pm {( {b}^{2} + {d}^{2} - 2 {{d}^{2} ( {d}^{2} + {b}^{2} )}^{\frac{1}{2}} )}^{\frac{1}{2}} & b \leq \sqrt{3} d\end{matrix} \\ = \begin{matrix}\pm {( {b}^{2} + {d}^{2} + 2 {{d}^{2} ( {d}^{2} + {b}^{2} )}^{\frac{1}{2}} )}^{\frac{1}{2}} & b > \sqrt{3} d\end{matrix}\end{matrix}$$

The values for the various gradients with these conditions can be tabulated in a spreadsheet, together with the corresponding dimension of the homogeneity volume. In the example spreadsheet of FIG. 5, a relative homogeneity of 10⁻⁴ (100 ppm) and d=0.15 m was used.

It can be seen that values of b/d nearly equal to \sqrt{3} produce the strongest field per ampere-turn. As an example we take b/d=1.5. Scaling this to give 1 tesla (NI=964570) gives the following:

G_{y2}=−5.32313E+01

G_{y3}=−8.90394E+02

G_{z2}=5.32315E+01

G_{z4}=−7.89067E+03

The field profiles are shown in FIG. 6 and the 10⁻⁴ contours are shown in FIG. 7.

X-Uniformity

This example used coils that were very long in the X-direction. To obtain useful designs, a method of correcting the uniformity in the X-direction should be applied.

The effects of the coils being of a realistic finite length (a few metres) are primarily to introduce negative second and fourth order gradients in the X-direction (Gₓ₂, Gₓ₄), and also to upset cancellation of the Y-gradient (G_{y1}). The following table plots the gradients as a function of the half-length of the coil system (the units are metres and tesla per ampere-turn):

| L | Gz0 | Gz2 | Gz4 | Gy1 | Gy2 | Gy3 | Gx2 | Gx4 | Gy1/Gx2 |
|---|---|---|---|---|---|---|---|---|---|
| inf | 1.036E−06 | 5.518E−05 | −8.156E−03 | 0.000E+00 | 2.212E−04 | −9.212E−04 | 0.000E+00 | 0.000E+00 | |
| 8 | 1.037E−06 | 5.519E−05 | −8.181E−03 | 2.063E−09 | −5.519E−05 | −9.231E−04 | −5.267E−13 | −3.270E−13 | −3917 |
| 4 | 1.037E−06 | 5.519E−05 | −8.181E−03 | 2.219E−09 | −5.519E−05 | −9.231E−04 | −2.875E−11 | −6.712E−11 | −77.19 |
| 2 | 1.036E−06 | 5.519E−05 | −8.181E−03 | 4.212E−09 | −5.519E−05 | −9.231E−04 | −1.284E−09 | −1.020E−08 | −3.280 |
| 1 | 1.033E−06 | 5.520E−05 | −8.181E−03 | 2.285E−08 | −5.517E−05 | −9.232E−04 | −3.684E−08 | −8.047E−07 | −0.620 |
| 0.5 | 1.016E−06 | 5.538E−05 | −8.185E−03 | 1.229E−07 | −5.487E−05 | −9.245E−04 | −5.115E−07 | −2.470E−05 | −0.240 |
| 0.25 | 9.613E−07 | 5.629E−05 | −8.202E−03 | 3.730E−07 | −5.299E−05 | −9.256E−04 | −3.302E−06 | −2.643E−04 | −0.113 |

It is possible to recover the G_{y1} cancellation by adjusting the width (b) of the coils, thus:

Variation of gradients with b for half-length=0.5 m

| b | Gz0 | Gz2 | Gz4 | Gy1 | Gy2 | Gy3 | Gx2 | Gx4 | Gy1/Gx2 |
|---|---|---|---|---|---|---|---|---|---|
| 0.215 | 9.358E−07 | 5.284E−05 | −5.122E−03 | −2.178E−07 | −5.233E−05 | −7.855E−04 | −5.166E−07 | −2.474E−05 | 0.422 |
| 0.216 | 9.436E−07 | 5.312E−05 | −5.391E−03 | −1.875E−07 | −5.261E−05 | −7.987E−04 | −5.162E−07 | −2.496E−05 | 0.363 |
| 0.217 | 9.514E−07 | 5.340E−05 | −5.668E−03 | −1.563E−07 | −5.289E−05 | −8.122E−04 | −5.157E−07 | −2.499E−05 | 0.303 |
| 0.218 | 9.593E−07 | 5.367E−05 | −5.953E−03 | −1.244E−07 | −5.316E−05 | −8.257E−04 | −5.153E−07 | −2.498E−05 | 0.241 |
| 0.219 | 9.673E−07 | 5.394E−05 | −6.246E−03 | −9.165E−08 | −5.342E−05 | −8.394E−04 | −5.148E−07 | −2.496E−05 | 0.178 |
| 0.220 | 9.753E−07 | 5.420E−05 | −6.548E−03 | −5.806E−08 | −5.368E−05 | −8.533E−04 | −5.143E−07 | −2.495E−05 | 0.113 |
| 0.221 | 9.833E−07 | 5.445E−05 | −6.858E−03 | −2.362E−08 | −5.393E−05 | −8.672E−04 | −5.138E−07 | −2.477E−05 | 0.046 |
| 0.222 | 9.914E−07 | 5.469E−05 | −7.176E−03 | 1.167E−08 | −5.418E−05 | −8.813E−04 | −5.132E−07 | −2.475E−05 | −0.023 |
| 0.223 | 9.996E−07 | 5.493E−05 | −7.503E−03 | 4.784E−08 | −5.442E−05 | −8.956E−04 | −5.127E−07 | −2.473E−05 | −0.093 |
| 0.224 | 1.008E−06 | 5.516E−05 | −7.840E−03 | 8.491E−08 | −5.465E−05 | −9.100E−04 | −5.121E−07 | −2.472E−05 | −0.166 |

However, it is not necessarily desirable to make this adjustment to exactly cancel G_{y1} because the correction coils will have their own Y-gradient that must be corrected.

The scheme for dealing with the X-gradients is analogous to the end-correction “Garrett coils” in the design of solenoid magnets. Here, we place two pairs of coils at the ends of main coils, and to allow for the physical size, slightly below them (greater value of “d”).

The following table plots the gradients for such a system, for two values of b, against the gap between the coils.

### Split Correction Coils:

L=0.5, d=0.175, b=0.225 ssr-ct.6.1

| gap | Gz0 | Gz2 | Gz4 | Gy1 | Gy2 | Gy3 | Gx2 | Gx4 | Gy1/Gx2 |
|---|---|---|---|---|---|---|---|---|---|
| 0.150 | 1.018E−06 | 4.068E−05 | −4.617E−03 | 5.930E−07 | −4.174E−05 | −6.584E−04 | 1.055E−06 | −6.331E−04 | 0.562 |
| 0.175 | 9.123E−07 | 3.357E−05 | −3.618E−03 | 2.747E−07 | −3.856E−05 | −5.530E−04 | 4.987E−06 | −1.146E−03 | 0.055 |
| 0.200 | 8.096E−07 | 2.683E−05 | −2.859E−03 | 6.499E−10 | −3.506E−05 | −4.527E−04 | 8.230E−06 | −1.425E−03 | 0.000 |
| 0.225 | 7.123E−07 | 2.075E−05 | −2.287E−03 | −2.213E−07 | −3.136E−05 | −3.612E−04 | 1.061E−05 | −1.476E−03 | −0.021 |
| 0.250 | 6.219E−07 | 1.550E−05 | −1.849E−03 | −3.893E−07 | −2.760E−05 | −2.811E−04 | 1.210E−05 | −1.352E−03 | −0.032 |
| 0.275 | 5.395E−07 | 1.117E−05 | −1.495E−03 | −5.060E−07 | −2.393E−05 | −2.136E−04 | 1.276E−05 | −1.117E−03 | −0.040 |
| 0.300 | 4.653E−07 | 7.729E−06 | −1.206E−03 | −5.778E−07 | −2.047E−05 | −1.586E−04 | 1.274E−05 | −8.404E−04 | −0.045 |
| 0.325 | 3.994E−07 | 5.089E−06 | −9.613E+00 | −6.122E−07 | −1.730E−05 | −1.153E−04 | 1.221E−05 | −5.709E−04 | −0.050 |
| 0.350 | 3.415E−07 | 3.133E−06 | −7.551E−04 | −6.176E−07 | −1.448E−05 | −8.201E−05 | 1.134E−05 | −3.387E−04 | −0.054 |
| 0.375 | 2.910E−07 | 1.734E−06 | −5.830E−04 | −6.015E−07 | −1.201E−05 | −5.711E−05 | 1.027E−05 | −1.556E−04 | −0.059 |
| 0.400 | 2.473E−07 | 7.689E−07 | −4.432E−04 | −5.705E−07 | −9.892E−06 | −3.886E−05 | 9.123E−06 | −2.422E−05 | −0.063 |
| 0.425 | 2.096E−07 | 1.315E−07 | −3.311E−04 | −5.301E−07 | −8.102E−06 | −2.577E−05 | 7.970E−06 | 6.244E−05 | −0.067 |
| 0.450 | 1.773E−07 | −2.668E−07 | −2.436E−04 | −4.845E−07 | −6.604E−06 | −1.655E−05 | 6.871E−06 | 1.136E−04 | −0.071 |
| 0.475 | 1.497E−07 | −4.956E−07 | −1.765E−04 | −4.368E−07 | −5.362E−06 | −1.018E−05 | 5.858E−06 | 1.388E−04 | −0.075 |
| 0.500 | 1.260E−07 | −6.079E−07 | −1.262E−04 | −3.891E−07 | −4.339E−06 | −5.874E−06 | 4.947E−06 | 1.456E−04 | −0.079 |

L=0.5, d=0.175, b=0.2 ssr-ct.6.2

| gap | Gz0 | Gz2 | Gz4 | Gy1 | Gy2 | Gy3 | Gx2 | Gx4 | Gy1/Gx2 |
|---|---|---|---|---|---|---|---|---|---|
| 0.150 | 7.932E−07 | 3.276E−05 | −1.882E−03 | −4.789E−08 | −3.492E−05 | −4.345E−04 | 2.161E−06 | −6.502E−04 | −0.022 |
| 0.175 | 7.085E−07 | 2.654E−05 | −1.637E−03 | −2.157E−07 | −3.154E−05 | −3.587E−04 | 4.992E−06 | −9.706E−04 | −0.043 |
| 0.200 | 6.273E−07 | 2.085E−05 | −1.448E−03 | −3.538E−07 | −2.809E−05 | −2.889E−04 | 7.242E−06 | −1.118E−03 | −0.049 |
| 0.225 | 5.509E−07 | 1.586E−05 | −1.284E−03 | −4.586E−07 | −2.468E−05 | −2.272E−04 | 8.818E−06 | −1.106E−03 | −0.052 |
| 0.250 | 4.803E−07 | 1.167E−05 | −1.130E−03 | −5.301E−07 | −2.140E−05 | −1.744E−04 | 9.725E−06 | −9.797E−04 | −0.055 |
| 0.275 | 4.162E−07 | 8.286E−06 | −9.740E−04 | −5.710E−07 | −1.833E−05 | −1.309E−04 | 1.004E−05 | −7.898E−04 | −0.057 |
| 0.300 | 3.587E−07 | 5.644E−06 | −8.196E−04 | −5.857E−07 | −1.552E−05 | −9.609E−05 | 9.877E−06 | −5.811E−04 | −0.059 |
| 0.325 | 3.076E−07 | 3.650E−06 | −6.722E−04 | −5.795E−07 | −1.302E−05 | −6.901E−05 | 9.368E−06 | −3.858E−04 | −0.062 |
| 0.350 | 2.628E−07 | 2.195E−06 | −5.380E−04 | −5.575E−07 | −1.083E−05 | −4.847E−05 | 8.632E−06 | −2.217E−04 | −0.065 |
| 0.375 | 2.237E−07 | 1.168E−06 | −4.200E−04 | −5.246E−07 | −8.941E−06 | −3.324E−05 | 7.773E−06 | −9.457E−05 | −0.067 |
| 0.400 | 1.899E−07 | 4.694E−07 | −3.211E−04 | −4.847E−07 | −7.338E−06 | −2.220E−05 | 6.869E−06 | −4.945E−06 | −0.071 |
| 0.425 | 1.607E−07 | 1.560E−08 | −2.408E−04 | −4.411E−07 | −5.992E−06 | −1.434E−05 | 5.976E−06 | 5.329E−05 | −0.074 |
| 0.450 | 1.356E−07 | −2.617E−07 | −1.775E−04 | −3.962E−07 | −4.871E−06 | −8.872E−06 | 5.132E−06 | 8.710E−05 | −0.077 |
| 0.475 | 1.141E−07 | −4.151E−07 | −1.288E−04 | −3.519E−07 | −3.943E−06 | −5.143E−06 | 4.358E−06 | 1.025E−04 | −0.081 |
| 0.500 | 9.564E−08 | −4.842E−07 | −9.210E−05 | −3.092E−07 | −3.180E−06 | −2.663E−06 | 3.664E−06 | 1.056E−04 | −0.084 |

To correct both the Gₓ₂ and G_{y1} of the combined system we choose coils where the ratios G_{y1}/Gₓ₂ are approximately equal for the main and correction coils. If the ratios Gₓ₂/Gₓ₄ are also approximately the same, we can cancel a lot of the fourth-order x-gradient as well. The ratio of ampere-turns of the correction coils to that of the main coils is then the ratios of the Gₓ₂s.

From the tables above, we can choose an example with the following properties:

| coils | a | b | d | length | gap |
|---|---|---|---|---|---|
| main | 0.3927 | 0.223 | 0.15 | 0.50 | — |
| correction | 0.3927 | 0.20 | 0.175 | 0.50 | 0.50 |

| | | | | | | | | | |
|---|---|---|---|---|---|---|---|---|---|
| b | Gz0 | Gz2 | Gz4 | Gy1 | Gy2 | Gy3 | Gx2 | Gx4 | Gy1/Gx2 |

main

| | | | | | | | | | |
|---|---|---|---|---|---|---|---|---|---|
| 0.223 | 9.996E−07 | 5.493E−05 | −7.503E−03 | 4.784E−08 | −5.442E−05 | −8.956E−04 | −5.127E−07 | −2.473E−05 | −0.093 |

correction

| | | | | | | | | | |
|---|---|---|---|---|---|---|---|---|---|
| 0.500 | 9.564E−08 | −4.842E−07 | −9.210E−05 | −3.092E−07 | −3.180E−06 | −2.663E−06 | 3.664E−06 | 1.056E−04 | −0.084 |

correction times ratio I2/I1 = 0.13993

| | | | | | | | | |
|---|---|---|---|---|---|---|---|---|
| | 1.338E−08 | −6.776E−08 | −1.289E−05 | −4.327E−08 | −4.449E−07 | −3.726E−07 | 5.127E−07 | 1.477E−05 |
| total | 1.0130E−06 | 5.486E−05 | −7.516E−03 | 4.573E−09 | −5.486E−05 | −8.960E−04 | 0.000E+00 | −9.962E−06 |

This system is illustrated in FIGS. 8 and 9 with the correction coils illustrated as circles at each end and beneath the plane of the racetrack coils.

FIG. 10 is a magnetic field plot in the Y- and Z-directions for this system, and FIG. 11 is a field plot in the X-direction, with two different abscissa scales. This produces 10⁻⁶ tesla/amp-turn. There is space for a winding section of 20×100 mm² so at a current density of 100 Amm² a field strength of 0.2 tesla should be attainable.

FIGS. 12, 13 and 14 show contours of

$$\frac{\partial B}{B} = {10}^{- 3}$$

and 10⁻⁴ in the Y-Z, X-Y and X-Z planes, respectively. From this it can be seen that the homogeneous region is about 6 mm diameter and 260 mm long, and contains no difficult regions. The effect of the “fingers” of field homogeneity in the Y-Z plane can be minimised by an RF transmitter coil which has a small extent in the Z-direction. A typical imaging procedure for this system would be to apply a selective 90° pulse, then apply a readout gradient in the X-direction during data acquisition, and then rotate the assembly through a small angle about the Z-axis to obtain the next line.

NMR Sensitivity

RF Coils

The simplest form of RF coil is a single racetrack coil 260, coplanar with the magnet coils as shown in FIG. 15.

We can investigate the uniformity, field strength and inductance as a function of the half-width, b, for a half-length of 0.15 m, as shown below.

| b | Lhenries/turn² | B₁tesla/NI | G₁ₓtesla/A/m | G_{2y}tesla/A/m² | NIfor 1 oersted | Ejoules for 1 oe | ${\vert \frac{δB}{B} \vert}_{x}$ | ${\vert \frac{δB}{B} \vert}_{y}$ |
|---|---|---|---|---|---|---|---|---|
| 0.02 | 3.477E−07 | 3.761E−07 | 5.210E−06 | −8.788E−05 | 265.87 | 0.0123 | 0.0346 | −7.30E−04 |
| 0.04 | 5.052E−07 | 7.234E−07 | 9.372E−06 | −1.491E−04 | 138.23 | 0.0048 | 0.0324 | −6.44E−04 |
| 0.06 | 6.604E−07 | 1.013E−06 | 1.200E−05 | −1.717E−04 | 98.71 | 0.0032 | 0.0296 | −5.30E−04 |
| 0.08 | 8.238E−07 | 1.233E−06 | 1.312E−05 | −1.620E−04 | 81.1 | 0.0027 | 0.0266 | −4.11E−04 |
| 0.10 | 9.635E−07 | 1.386E−06 | 1.308E−05 | −1.348E−04 | 72.17 | 0.0025 | 0.0236 | −3.04E−04 |
| 0.12 | 1.10E−006 | 1.48E−006 | 1.23E−005 | −1.03E−004 | 67.52 | 0.0025 | 0.0208 | −2.17E−04 |
| 0.14 | 1.26E−006 | 1.53E−006 | 1.12E−005 | −7.36E−005 | 65.29 | 0.0027 | 0.0183 | −1.50E−04 |
| 0.16 | 1.43E−006 | 1.55E−006 | 9.94E−006 | −5.00E−005 | 64.54 | 0.0030 | 0.0160 | −1.01E−04 |

The NMR sensitivity is determined by the receptivity of the RF coil, which depends on the geometry, the noise resistance of the coil, and the noise resistance of the subject.

Coil Resistance

The coil resistance can be calculated from the skin depth. Using the coil with b=0.10 m as an example and a coil wire diameter of 2 mm, and taking the field strength as B₀=0.2 tesla, then f₀=8.5 MHz and δ=2.44×10⁻⁵ m, the coil resistance and Q can be tabulated against the number of turns:

| N | L henries | R ohms | Q |
|---|---|---|---|
| 1 | 9.635E−07 | 0.16 | 321.58 |
| 2 | 3.854E−06 | 0.32 | 643.17 |
| 4 | 1.542E−05 | 0.64 | 1286.33 |
| 8 | 6.166E−05 | 1.28 | 2572.66 |
| 16 | 2.467E−04 | 2.56 | 5145.32 |

Subject Resistance

The calculation of the effective noise resistance of the subject, as reflected in the RF coil, is not straightforward with this geometry.

Hoult and LauterburHoult, D and Lauterbur, P, J. Mag. Res. 34, 425-433 (1979) describe the following method:

1. Divide the subject into elementary cylinders, coaxial with the B₁ field direction, of conductance.

$$d G = \frac{l ( r ) dr}{2 π rρ}$$

For a sphere, l(r)=2\sqrt{b²−r²} where b is the radius of the sphere.
2. The EMF induced around the cylinder by the B₁ field is

$$V = π {r}^{2} \frac{\partial {B}_{1}}{\partial t} = π {r}^{2} {ω}_{0} {B}_{1} sin ( {ω}_{0} t )$$

3. The power dissipated in the sample is

$$W = \int {V}^{2} d G = \int \frac{{π}^{2}}{4 ρ} {r}^{3} {ω}_{0}^{2} {B}_{1}^{2} ( r ) l ( r ) d r$$

4. The effective series resistance reflected in the coil circuit is then given by

$$\frac{{I}^{2} R}{2} = W$$

where I is the amplitude of the current to give the field strength B₁.

This depends on there being considerable symmetry in the system. Hoult and Lauterbur consider only spherical subjects and solenoid or saddle coils. Their results therefore do not apply readily to this case, but a similar argument can be used.

We divide the subject into slices whose plane is perpendicular to B₁ and each slice is divided into a number of rectangular elements, of side 2a×2b as shown in FIG. 16.

The total emf around the ith element is

$$\frac{\partial {N}_{i}}{\partial t} = {ω}_{0} {N}_{i} sin ( {ω}_{0} t )$$

where Nᵢ is the B₁ flux linking the element. The emf on the jth side, of length 2a, is

$${ω}_{0} {N}_{i} sin ( {ω}_{0} t ) \cdot \frac{a}{2 ( a + b )}$$

On each side, the induced emf is offset by that of the neighbouring element so we must subtract the corresponding emf so that

$${V}_{i , j} = {ω}_{0} sin ( {ω}_{0} t ) \cdot \frac{a}{( a + b )} ( {N}_{i} - {N}_{i + 1} ) etc$$

We now assume that the corresponding current path is parallel to the side and occupies the triangular space, shown in the diagram. The emf across an element of width dx is

$$V \cdot \frac{x}{b}$$

and its conductance is

$$\frac{gbdx}{ρ a x} .$$

The power dissipated in the region associated with this side of the element is therefore

$$W = {V}^{2} {\int }_{0}^{b} \frac{{x}^{2}}{{b}^{2}} \cdot \frac{gb}{ρ ax} d x = \frac{{V}^{2} gb}{2 ρ a} \frac{1}{2}$$

where g is the thickness of the slice, the factor ½ comes from using the RMS power, and V has been obtained from the method outlined above.

The effective subject resistance has been calculated using the sort of subdivision illustrated in FIGS. 17a and 17b.

The subject was assumed to be a cylindrical volume, of radius 0.15 m (effectively filling the available volume—a worst case—with the RF coil positioned 0.15 m from the centre point) and conductivity 0.85 Ωm⁵. Two different subdivisions were used, and the flux linkage with the RF coil was calculated using existing software. The results are summarised below (Hoult & Lauterbur calculation assumes a pair of saddle coils on a 0.3 m diameter).

| slices | axial divisions | total length | R_{effective}Ω |
|---|---|---|---|
| 5 | 3 | 0.6 m | 2.19 |
| 7 | 5 | 0.75 m | 1.61 |

| | | |
|---|---|---|
| Hoult & Lauterbur | 0.3 m sphere | 0.76 |

Signal-Noise Ratio

Using the coil described above, and the effective subject resistance of 1.61Ω, the signal-to-noise ratio can be estimated as a function of resolution along the line in the X-direction, assuming a 3 mm radius at resonance. This is shown as a function of field strength and spatial resolution (pixels in 0.2 m) in FIG. 18.

Image Reconstruction

To apply this system to an NMR imaging procedure, we should postulate a pulse sequence. The simplest possible pulse sequence would be
90°-τ-180°-τ-G_{acquire}^{x}

Of course, this does not preclude the use of more complex pulse sequences with this apparatus, such as may be required for T₁ or T₂ weighting of the image. We use this sequence to examine the requirements for pulse lengths, B₁ strengths and power deposition, so as to show the feasibility. More elaborate pulse sequences might also be desirable, so we should also examine the larger spectral contents required when an RF pulse is applied while the gradient is on.

The magnet is designed to produce a long, thin volume of uniform B₀ field. The coordinate system which is fixed to the magnet is [x′, y′, z′] with \vec{B}₀=[0,0,B_{0z′}] and with the volume of uniformity aligned in the x′ direction. In the laboratory frame [x,y,z], the magnet can be rotated about the z axis so that

x′=x cos θ|y sin θ, y′=x sin θ|y cos θ, z′=z.

A selective excitation at the frequency γB₀ selects spins in this volume and we can apply a refocusing pulse and receive signal in the presence of a gradient G_{x′}. We detect this signal at the frequency ν₀=γB₀. Representing the density of spins over the subject as g(x,y) and remembering that the gradient maps the spatial distribution along the gradient direction into the frequency, ν, of the received signal so that

$${x}^{′} \frac{υ}{γ {G}_{{x}^{′}}} , {y}^{′} = 0 , ,$$

and our projection, obtained by integrating over the sensitive volume is

$${ζ}_{θ} ( υ ) = \frac{A}{γ {G}_{{x}^{′}}} \int g ( \frac{υ}{γ {G}_{{x}^{′}}} cos θ , \frac{υ}{γ {G}_{{x}^{′}}} sin θ ) d v$$

This can be filtered, Fourier-transformed and summed to recover the density distribution function g(x,y). The assumption is made that the variation of B₀+G_{x′}x′ over the cross-section of the sensitive volume is small compared with G_{x′}δx′ where δx′ is the spatial resolution in the radial direction.

Gradient Strength

The gradient G_{x′} should be, strong enough to swamp the effects of B₀ inhomogeneity. Taking B₀=0.2 T and δB=2×10⁻⁵ T over the sensitive volume we require G_{x′}δx>δB, say G_{x′}δx=2δB where δx=L/Nₚ, L is the length of the sensitive volume, =0.2 m and Nₚ is the number of pixels along the projection.

| Nₚ | G_{x′} | Rₓbandwidth |
|---|---|---|
| 32 | 0.0064 T/m | 55 kHz |
| 64 | 0.0128 | 109 |
| 128 | 0.0256 | 218 |
| 256 | 0.0512 | 436 |

B₁ Field Strength and Pulse Length

1) 180° Pulse with No Gradient

The required bandwidth is γδB=850 Hz, so we can expect a pulse length of ≈1.17×10⁻³ sec. To achieve a 180° flip in this time requires a field strength of

$$\frac{π}{2 πγ r} = 1 \times {10}^{- 5} Tesla .$$

Using the coil system and sample resistance calculation described earlier, we have:

| Nₜᵤᵣₙₛ | L | R_{coil} | R_{subject} | Q | B₁/I | I₁₈₀ | W_{subject} |
|---|---|---|---|---|---|---|---|
| 1 | 9.64 × 10⁻⁷ H | 0.16 ohms | 1.61 ohms | 29.1 | 1.39 × 10⁻⁶ T/A | 7.22 amp | 83.8 wat |
| 2 | 3.85 × 10⁻⁷ H | 0.32 | 6.44 | 30.5 | 2.77 × 10⁻⁶ | 3.61 | 83.8 |
| 4 | 1.54 × 10⁻⁷ H | 0.64 | 25.76 | 31.3 | 5.54 × 10⁻⁶ | 1.80 | 83.8 |
| 8 | 6.17 × 10⁻⁷ H | 1.28 | 103.0 | 31.6 | 1.11 × 10⁻⁵ | 0.90 | 83.8 |

If we assume a recycle time of 0.1 sec, the mean power deposited in the subject is 2.2 W. Using the assumptions discussed earlier, the power per unit volume is between 1.6 and 2.8 W/l peak, 40 to 70 m W/l mean.

2) 180° Pulse with Gradient

As the gradient strength depends on the number of pixels, so must the pulse length:

| Nₚ | τ | B₁ for 180° | mean W_{subject} |
|---|---|---|---|
| 32 | 18.4 μs | 6.4 × 10⁻⁴ tesla | 63 watt |
| 64 | 9.2 | 1.28 × 10⁻³ | 126 |
| 128 | 4.6 | 2.56 × 10⁻³ | 252 |
| 256 | 2.3 | 5.12 × 10⁻³ | 504 |

Again the values for the mean subject power is for a single 180° pulse repeated every 0.1 sec. This is therefore about 100 times greater than in the previous section, but is still not exceptional.

Saturation Effects

Regions near the centre of the imaging plane will be subjected to overlapping projections. The overlapping volumes can be minimised by taking projections at say 0°, 90°, 1.4°, 91.40 . . . (for 128 projections) doubling the time allowing the magnetisation to relax. For T₁≈0.8 sec it might then take about a minute to complete a scan of a plane. However, the resulting scan might have an artifact consisting of a 6 mm radius “hole” in the centre.

Mechanical System

Examples of suitable magnet systems for performing the invention have been discussed in detail above. This has focussed primarily upon the magnet itself and the related feasibility calculations.

We now consider achieving the relative movement. As discussed earlier, the subject and/or target itself can be moved or rotated so as to provide the possibility of obtaining magnetic resonance information from a plane or indeed a volume. Depending on the particular arrangement, it may be advantageous to move the subject rather than the magnet system since the subject will likely be of considerably smaller mass than the system itself. This might not always be the case however. For example during delicate surgery upon a patient (target) it may be desirable for the patient to remain motionless and for the magnet system to be moved so as to perform an MRI scan. Depending upon the arrangement of the system, the medical practitioners could step aside or away from the patient during the scan since they might otherwise obstruct the magnet movement.

In a simple example of a stationary magnet system, a patient subject may be placed upon a table lying substantially parallel to the X-Z plane. If the system is aligned such that the part of the patient of interest is coincident with the centre of the sensitive volume, then a simple rotation about the Y-axis by 180° allows the linear sensitive volume to trace out a X-Z planar disc.

An example of this is shown in FIG. 19 which is a side view of a superconducting magnet system 100 as described earlier with the elongate direction X of the coils lying in a direction into the plane of the figure. As illustrated, a patient 200 is positioned upon a table 201. The origin of the co-ordinate system (and centre of the sensitive volume) is positioned within the abdomen of the patient for performing abdominal MRI. Table 201 is formed from a suitable material for use with MRI. In this case, the table is supported from beneath at a central location by a hydraulic ram 203 that is operable so as to move the table in a direction (up and down) illustrated by arrow 202. The ram and table are also rotatable about the axis defined by the direction 202. This is achieved using a drive motor 204. A control system (not shown) is used to control the movement of the patient 200 in accordance with taking magnetic resonance measurements from the sensitive volume.

FIG. 20 shows a schematic view of how the system is operated to perform a scan of a region in the X-Z plane by the movement of the patient 200. The sensitive volume 10 is illustrated, as are the first coil pairs of the magnet system 100. As shown, the patient 200 is rotated about an axis perpendicular to the plane of the drawing, this axis passing through the centre of the sensitive volume 10 such that, with respective to the patient, the sensitive volume traces out a planar disc by rotation of the patient with respect to the magnet system (the rotation being illustrated by the arrows 205). A rotation by 180° allows the sensitive volume 10 to trace out a circular plane. Having completed this rotation, the hydraulic ram 203 can be operated so as to move the patient 200 in the vertical direction 202 so as to allow an adjacent plane within the patient to be imaged. In this way, a three dimensional (cylindrical) image can be built up from traced out planar slices.

In an alternative to this hydraulic and motorised arrangement, the movement of the patient can be effected in other ways. For example, the ends of the table 201 could be arranged on wheels that follow a helical track which orbits the patient. The helix in this case would have an axis along the direction 202 and would allow information to be obtained from a similar region of the patient as described in accordance with FIGS. 19 and 20 above. The use of a helical path rather than separate rotation and axial (vertical) movements makes the mathematics of reconstructing the image more complicated. Nevertheless, this is still achievable.

Whilst in this example the patient is rotated, equally the magnet system could also be rotated. A similar mechanism of tracks, motors or hydraulics could be used to achieve this.

We have not described such engineering details greatly here since the technical field of medical apparatus includes analogous technologies, for example in the production of scanning X-ray machines. Therefore the means to implement such relative movements are within the abilities of a person of ordinary skill.

FIG. 21 shows an alternative system in which the axis of the patient is positioned normal to the magnet system and relative motion is performed by rotational movement, as illustrated by the arrow 250. In addition, axial movement is provided in the direction 251. Again, the patient or the magnet system can be rotated. In this case, the distance between the two main “racetrack” coils of the system is sufficient to accommodate the body of the patient. The patient can therefore stand in this position and the main system be rotated around them or vice versa. Of course, the patient could also be positioned in a lying orientation, with the elongate direction X of the coils rotating in a vertical plane (this being achieved by rotating the FIG. 21 by 90°).

FIG. 22 is another example in which part of the body of a patient 202, for example the head, is scanned by a magnet system that orbits the head of the patient. The patient can therefore be seated and the magnet system performs a partial orbit of the head so as to rotate the sensitive volume 10 through desired plane. Vertical movement for other planar slices (in a direction normal to the plane of the drawing) can also be provided. Such a system could be used to perform brain imaging for example.

In addition or alternatively to rotations of the sensitive volume 10 with respect to the target patient, linear translations may also be performed so as to obtain magnetic resonance information from the plane by movement of the sensitive volume in a direction perpendicular to the axis of the sensitive volume. Such movements could be combined with translations normal to the plane to image a three dimensional volume.

Implementations Using Superconductors

In overall terms, superconductors are desirable for constructing all of the magnets described above because they provide for high current densities in the poles such that appropriate levels of field intensity for magnetic resonance may be projected useful distances beyond the magnet. High temperature superconductors (HTS) are useful when it is required to change the current in coil sets so as to electrically alter the projection distance for MRI, and to undertake MRI in a selected plane by back projection methods.

A simple arrangement of coils described herein can provide for a homogeneous zone (sensitive volume) with the profile of a rod. The rod would be located above the plane of the pole faces, for convenient size magnets, some 0.1 to 0.4, preferably 0.25 m beyond the plane, with a length determined by the length of the race-track pole set, and a diameter of some tens of millimetres. The purpose of the systems disclosed herein is to arrange for the mechanical rotation of the homogeneous rod about an axis of rotation, so as to define an image plane. This allows for a MRI scan method analogous to X-ray CT imaging by back projection within the plane. For each angular position of the homogeneous rod, one projection in the image plane can be obtained. An image slice is reconstructed of the subject matter in the image plane. As will be understood, the magnet coils of the system are arranged to provide a small imaging field gradient along the “homogeneous” rod for pixel selection.

Mechanical Movement

The racetrack coils may be physically rotated about the subject to create a set of projections by imaging in the sensitive volume, which would rotate with the magnet. Most conveniently, it would be desirable to rotate the magnet under a patient bed and take an image slice in a plane parallel to the plane of the bed on which the patient lies. In order to move the image plane up or down in relation to the bed, the magnet set could be moved closer to or away from the underside of the bed. This is a purely mechanical “MRI CT” system.

It should be noted here, that Low Tc superconductors provide enough current density for creating useful levels of field projection, but the necessary cryogenics required for operation at or below 9K (to include Niobium tin) may place restrictions on mechanical movements. For example, cryostats for liquid Helium are cumbersome, but also delicate and should be carefully constructed to allow rapid rotation of the magnet. Further, when refrigerators are attached to the Helium cryostat, to obtain a self-sufficient magnet system, the complex nature of the refrigerators does limit design options for movements required for projection methods.

Because HTS conductors can be operated at temperatures up to about 77 degrees Kelvin, cryostats for the magnet, and refrigerators for self-sufficient operation can be simple, allowing for a wider choice of mechanical movement regimes.

HTS Superconductions

The benefits of using HTS superconductors magnets are derived from minimising the consequences of internal heat effects. Some of these effects are now discussed.

AC losses

High temperature superconductors remain in the superconducting state while retaining useful current density up to about the boiling point of liquid nitrogen (77K at atmospheric pressure). In general, the refrigeration power required to compensate heat losses from the cryostat increases as a power law between dT ̂2 and dT\hat{3}, where dT is the difference between the magnet and environment temperatures. Superconductors are subject to AC current losses as are normal conductors. The source of these losses is eddy currents produced by a changing magnetic field in the conductor, and hysteretic losses as local levels of magnetisation change in the superconductor. Thus, the higher the operating temperature in the sense of being closer to ambient environment temperature, the more efficiently the refrigeration will cope with AC losses.

Conductor Stability Against AC Losses

In the windings of the magnets, heat effects due to AC losses will be initiated in the conductor itself. So that the winding may be a rigid structure, particularly because of the straight sides, turns of conductor will be bonded together, and turns must be electrically insulated. Thus heat generated within the winding must be conducted to the refrigeration coolant through the conductor. This will raise the temperature of the conductor locally.

By using HTS conductor at a temperature closer to that of the environment than it is possible for a Low temperature superconductor to be used, the rise in temperature in the winding from AC losses of a given power will be reduced. In the HTS conductor, the AC losses occur at a higher temperature. As the temperature of any material is increased, the specific heat of the material will increase (approx as T̂3). Thus, given AC power losses produce a smaller temperature rise in High temperature windings than in Low temperature windings.

Such temperature rise as occurs for a given power of AC loss in the HTS windings, while being reduced compared to a Low temperature superconductor windings, will also be a smaller fraction of the temperature range over which the HTS conductor will carry a super current. Thus, larger AC power losses can be tolerated in a HTS before superconductivity is lost.

Conductor Stability Against Mechanical Disruption

A magnet winding is subject to an internal electromagnetic pressure, due to the forces on the conductor carrying current in the winding interacting with the magnetic field produced by the winding. This “pressure” creates a stress in the winding, and the winding will undergo strain in response to the stress. How much strain occurs for a given field will depend on the material characteristics of the conductor, the bonding agent, and the support structure. Initially, uniform strain will be elastic, as forces increase, plastic deformation will occur, although this latter stage will result in permanent damage to the winding.

The mechanical work done on the winding by the stress-strain situation results in heat being released in the winding. The release of heat due to mechanical effects must be considered in the same way as that generated by AC losses. Usually, when magnet windings behave as composite structures, the stress produced by electromagnetic forces, while causing a uniform response ultimately throughout the pressure vessel, will initially cause local microscopic mechanical responses. The local strain may give rise to local temperature rises that can cause superconductivity to be lost. As with the AC power dissipation, HTS conductors will accommodate local mechanical work more readily than Low temperature superconductors.

The magnets described here have straight sides, and are subject to bending forces in the winding along the straight sides. It is known that straight-sided magnets, constructed from Low temperature superconductors, must be operated at lesser magnetic pressure than magnets with cylindrical geometry. Thus it is beneficial in producing a moving zone of homogeneity, if such a winding is constructed of HTS conductor.

1. Magnetic resonance apparatus comprising:
a single-sided magnet having a first pair of coils each being elongate in a direction X and arranged in a plane with the direction X being substantially parallel to said plane, the coils being operable in a counter-running manner when in use so as to generate a sensitive volume of magnetic field spaced apart from said plane, the magnetic field in the sensitive volume being substantially uniform thereby having sufficient uniformity to enable magnetic resonance signals to be obtained from a target when located within the sensitive volume, the magnetic field direction Z lying substantially parallel to said plane, and wherein the coils are arranged such that the sensitive volume is also elongate in a direction X substantially parallel to said plane; and,
a drive system adapted in use to cause relative movement between the magnet and the target so as to allow the sensitive volume to be moved with respect to the target;
wherein the magnetic field generated in the sensitive volume does not include a contribution from coils that are counter-running with respect to the first pair, such that the sensitive volume is substantially a line.

2. Apparatus according to claim 1, wherein the sensitive volume is arranged to be to one side of and separate from the plane.

3. Apparatus according to claim 1, wherein each of the coils has an axis substantially perpendicular to the turns of the coil and which is substantially perpendicular to a respective plane thereof.

4. Apparatus according to claim 1 wherein the sensitive volume is substantially a line in the form of an elongate volume of small cross sectional dimensions.

5. Apparatus according to claim 4, wherein part of each coil within the first pair is rectilinear in the X direction.

6. Apparatus according to claim 5, wherein each coil within the first pair has two parallel straight parts.

7. Apparatus according to claim 6, wherein the part of each coil joining two rectilinear parts defines a single curve.

8. Apparatus according to claim 4, wherein each of the coils is of the same length in the X direction.

9. Apparatus according to claim 4, wherein the elongate coils each comprise a set of sub-coils arranged in the X direction so as to act together as an elongate coil.

10. Apparatus according to claim 4, further comprising two pairs of correction coils, one pair being located at each end of the elongate coils so as to control the extent of the sensitive volume in the X direction.

11. Apparatus according to claim 10, wherein the correction coils define a plane parallel with the plane of the first pair.

12. Apparatus according to claim 10, wherein the correction coils have a circular geometry.

13. Apparatus according to claim 1, wherein the coils are formed from high temperature superconducting materials.

14. Apparatus according to claim 1, wherein the drive system is adapted to move the sensitive volume in a plane defining a working plane with respect to the target.

15. Apparatus according to claim 14, wherein the drive system is adapted to rotate the sensitive volume about a point lying on a line defined by an elongate axis of the sensitive volume.

16. Apparatus according to claim 15, wherein the point is located at substantially the centre of the sensitive volume.

17. Apparatus according to claim 15, wherein the point is located at substantially one end of the sensitive volume.

18. Apparatus according to claim 15, wherein the sensitive volume is rotated in the X-Z plane.

19. Apparatus according to claim 15, wherein the sensitive volume is rotated in the X-Y plane.

20. Apparatus according to claim 1, wherein the sensitive volume is linearly translated in a plane defining a working X-Z plane, normal to the direction of elongation of the sensitive volume.

21. Apparatus according to claim 1, wherein the sensitive volume is linearly translated in a plane defining a working X-Y plane, normal to the direction of elongation of the sensitive volume, wherein the Y direction is mutually perpendicular to the X and Z directions.

22. Apparatus according to claim 1, wherein the drive system is further adapted to move the sensitive volume in a direction having at least a component normal to the working plane with respect to the target.

23. Apparatus according to claim 22, wherein the drive system is adapted to move the sensitive volume substantially normal to the working plane.

24. Apparatus according to claim 1, wherein the sensitive volume is an elongate prism having a diameter of 10 millimetres or less.

25. Apparatus according to claim 1, wherein the sensitive volume is spaced to one side of the plane defined by the first coil pair, by a distance of about 0.25 metres.

26. Apparatus according to claim 1, wherein the drive system is adapted to move the target, with the magnet remaining stationary.

27. Apparatus according to claim 1, wherein the drive system is adapted to move the magnet, with the target remaining stationary.

28. Apparatus according to claim 1, wherein the drive system is adapted to move the magnet and the target relative to an external reference position.

29. Apparatus according to claim 1, further comprising a set of gradient coils for producing a gradient in the magnetic field along the X direction within the sensitive volume.

30. Apparatus according to claim 29, wherein the set of gradient coils comprise pairs of gradient coils arranged at or adjacent the respective ends of the first pair.

31. Apparatus according to claim 29, wherein the set of gradient coils comprises coils that are elongate in a common direction with the elongation of the first pair and which have a centroid that is offset in the said direction of elongation when compared with the centroid of the first pair of coils.

32. Apparatus according to claim 1 further comprising one or more transmit and/or receive coils for obtaining the magnetic resonance signals from the target when in the sensitive volume.

33. Magnetic resonance apparatus according to claim 1, wherein each coil in the first pair has opposing ends which are angled out of the corresponding plane so as to increase the homogeneity of the region within the direction X in comparison with similar coils lying wholly within the plane.

34. A method of using magnetic resonance apparatus according to claim 1, the method comprising:
a) positioning the sensitive volume at a first position with respect to the target;
b) operating the apparatus to obtain magnetic resonance signals from the target within the sensitive volume;
c) operating the drive system to cause the sensitive volume to move to a different position with respect to the target; and,
d) repeating steps b and c so as to obtain magnetic resonance signals from a number of different positions.
